(19) United States
(12) Patent Application Publication
(10) Pub. No.: US 2014/0362962 A1
(43) Pub. Date: Dec. 11, 2014

(54) System and Method For Adaptive N-Phase Clock Generation For An N-Phase Receiver

(71) Applicant: Avago Technologies General IP (Singapore) Pte. Ltd., Singapore (SG)

(72) Inventors: Peter J. Meier, Fort Collins, CO (US); Gilbert Yoh, Fort Collins, CO (US); Darrin C. Miller, Fort Collins, CO (US); Jade Michael Kizer, Windsor, CO (US)

(21) Appl. No.: 13/913,553

(22) Filed: Jun. 10, 2013

(51) Int. Cl. H03L 7/085; H04L 7/033

(52) U.S. Cl. CPC H03L 7/085; H04L 7/033
USPC 375/375

(57) ABSTRACT

An N-phase clock generation circuit includes an input clock signal comprising a first phase signal, a phase interpolator configured to receive the input clock signal and generate a second phase signal, a first divider element configured to receive the first phase signal and generate an in-phase divided clock signal, a second divider element configured to receive the second phase signal and generate a quadrature divided clock signal, a first delay element configured to receive the in-phase divided clock signal and an in-phase control signal, the first delay element configured to generate a delayed in-phase divided clock signal, an a second delay element configured to receive the quadrature divided clock signal and a quadrature control signal, the second delay element configured to generate a delayed quadrature divided clock signal.

### BACKGROUND

A modern integrated circuit (IC) must meet very stringent design and performance specifications. In many applications for communication devices, transmit and receive signals are exchanged over communication channels. These communication channels include impairments that affect the quality of the signal that traverses them. One type of IC that uses both a transmit element and a receive element is referred to as a serializer/deserializer (SERDES). The transmit element on a SERDES typically sends information to a receiver on a different SERDES over a communication channel. The communication channel is typically located on a different structure from where the SERDES is located. To correct for impairments introduced by the communication channel, a transmitter and/or a receiver on a SERDES or other IC may include circuitry that performs channel equalization and other methods of validating the received data. One of the functions performed at a receiver is the generation of appropriate clocking signals to allow the receiver to properly receive and decode the received signal.

Some of the challenges with clock generation are exacerbated when implementing a pipelined receiver system. A pipelined receiver is one that processes multiple streams of data in parallel, where the multiple streams of data are separated in phase. Clock generation becomes even more challenging when attempting to design and fabricate a receiver that can operate using both PAM 2 and PAM 4 modalities. The acronym PAM refers to pulse amplitude modulation, which is a form of signal modulation where the message information is encoded into the amplitude of a series of signal pulses. PAM is an analog pulse modulation scheme in which the amplitude of a train of carrier pulses is varied according to the sample value of the message signal. A PAM 2 communication modality refers to a modulator that takes one bit at a time and maps the signal amplitude to one of two possible levels (two symbols), for example −1 volt and 1 volt. A PAM 4 communication modality refers to a modulator that takes two bits at a time and maps the signal amplitude to one of four possible levels (four symbols), for example −3 volts, −1 volt, 1 volt, and 3 volts. For a given baud rate, PAM 4 modulation can transmit up to twice the number of bits as PAM 2 modulation.

Therefore, it would be desirable to have a way to implement a clock generator in a receiver that can generate multiple clock signals and that is useful for both PAM 2 and PAM 4 modalities.

### SUMMARY

In an embodiment, an N-phase clock generation circuit comprises an input clock signal comprising a first phase signal, a phase interpolator configured to receive the input clock signal and generate a second phase signal, a first divider element configured to receive the first phase signal and generate an in-phase divided clock signal, a second divider element configured to receive the second phase signal and generate a quadrature divided clock signal, a first delay element configured to receive the in-phase divided clock signal and an in-phase control signal, the first delay element configured to generate a delayed in-phase divided clock signal, an a second delay element configured to receive the quadrature divided clock signal and a quadrature control signal, the second delay element configured to generate a delayed quadrature divided clock signal.

Other embodiments are also provided. Other systems, methods, features, and advantages of the invention will be or will become apparent to one with skill in the art upon examination of the following figures and detailed description. It is intended that all such additional systems, methods, features, and advantages be included within this description, be within the scope of the invention, and be protected by the accompanying claims.

### BRIEF DESCRIPTION OF THE DRAWINGS

The invention can be better understood with reference to the following drawings. The components in the drawings are not necessarily to scale, emphasis instead being placed upon clearly illustrating the principles of the present invention. Moreover, in the drawings, like reference numerals designate corresponding parts throughout the several views.

FIG. 1 is a schematic view illustrating an example of a communication system in which the system and method for adaptive N-phase clock generation for an N-phase receiver can be implemented.

FIG. 2 is a schematic diagram illustrating an example receiver of FIG. 1.

FIG. 3 is a schematic diagram illustrating example clock signals of the receiver of FIG. 2.

FIG. 4 is a block diagram illustrating an embodiment of the N-phase clock generation circuit of FIG. 2.

FIG. 5 is a block diagram illustrating an alternative embodiment of the N-phase clock generation circuit of FIG. 2.

FIG. 6 is a diagram showing the signal traces of FIG. 4 and FIG. 5.

FIG. 7 is a block diagram showing an example of the phase interpolator of FIG. 4 and FIG. 5.

FIG. 8 is a flow chart describing an embodiment of a method for adaptive

N-phase clock generation for an N-phase receiver.

FIG. 9 is a flow chart describing an alternative embodiment of a method for adaptive N-phase clock generation for an N-phase receiver.

### DETAILED DESCRIPTION

A system and method for adaptive N-phase clock generation for an N-phase receiver can be implemented in any integrated circuit (IC) that uses a digital direct conversion receiver (DCR) to receive a communication signal over a communication channel. In an embodiment, the system and method for adaptive N-phase clock generation for an N-phase receiver is implemented in a serializer/deserializer (SERDES) receiver operating at a 50 gigabit per second (Gbps) data rate by implementing a pulse amplitude modulation (PAM) 4 modulation methodology operating at 25 GBaud (Gsymbols per second). The 50 Gbps data rate is enabled, at least in part, by the pipelined implementation to be described below, and is backward compatible with PAM 2 modulation methodologies operating at a data rate of 25 Gbps.

As used herein, the term “cursor” refers to a subject bit, the term “pre-cursor” or “pre” refers to a bit that precedes the “cursor” bit and the term “post-cursor” or “post” refers to a bit that is subsequent to the “cursor” bit.

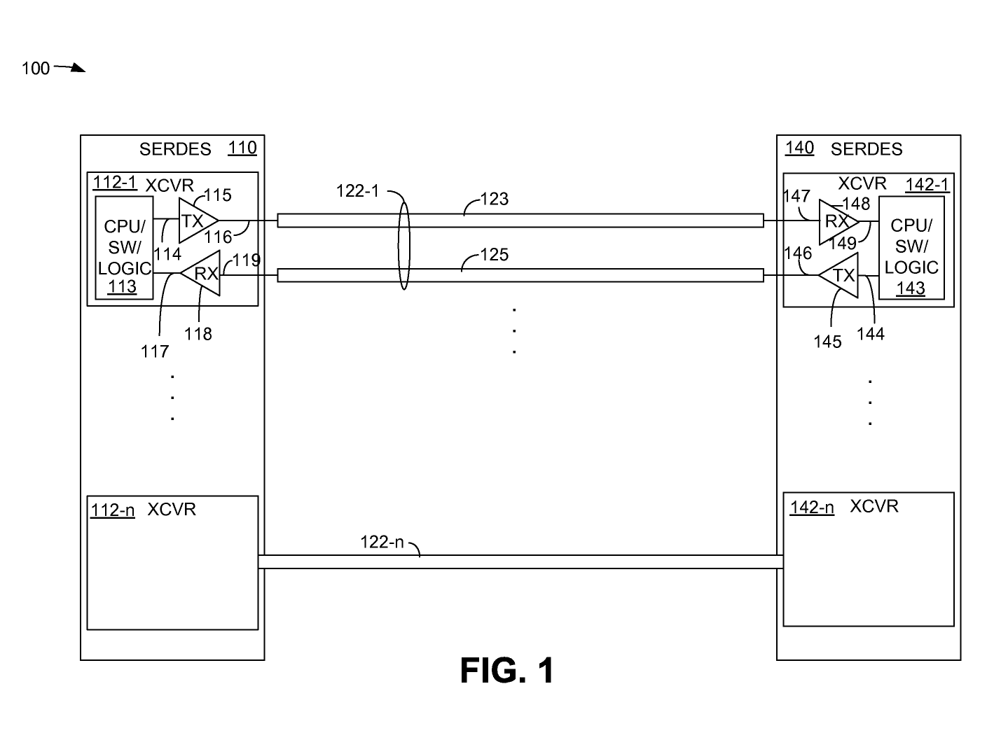

FIG. 1 is a schematic view illustrating an example of a communication system 100 in which the adaptive modal PAM2/PAM4 in-phase (I) quadrature (Q) (I/Q) phase detector for a receiver can be implemented. The communication system 100 is an example only of one possible implementation. The communication system 100 comprises a serializer/deserializer (SERDES) 110 that includes a plurality of transceivers 112. Only one transceiver 112-1 is illustrated in detail, but it is understood that many transceivers 112-n can be included in the SERDES 110.

The transceiver 112-1 comprises logic 113, which includes the functionality of a central processor unit (CPU), software (SW) and general logic, and will be referred to as “logic” for simplicity. It should be noted that the depiction of the transceiver 112-1 is highly simplified and intended to illustrate only the basic components of a SERDES transceiver.

The transceiver 112-1 also comprises a transmitter 115 and a receiver 118. The transmitter 115 receives an information signal from the logic 113 over connection 114 and provides a transmit signal over connection 116. The receiver 118 receives an information signal over connection 119 and provides a processed information signal over connection 117 to the logic 113.

The system 100 also comprises a SERDES 140 that includes a plurality of transceivers 142. Only one transceiver 142-1 is illustrated in detail, but it is understood that many transceivers 142-n can be included in the SERDES 140.

The transceiver 142-1 comprises a logic element 143, which includes the functionality of a central processor unit (CPU), software (SW) and general logic, and will be referred to as “logic” for simplicity. It should be noted that the depiction of the transceiver 142-1 is highly simplified and intended to illustrate only the basic components of a SERDES transceiver.

The transceiver 142-1 also comprises a transmitter 145 and a receiver 148. The transmitter 145 receives an information signal from the logic 143 over connection 144 and provides a transmit signal over connection 146. The receiver 148 receives an information signal over connection 147 and provides a processed information signal over connection 149 to the logic 143.

The transceiver 112-1 is connected to the transceiver 142-1 over a communication channel 122-1. A similar communication channel 122-n connects the “n” transceiver 112-n to a corresponding “n” transceiver 142-n.

In an embodiment, the communication channel 122-1 can comprise communication paths 123 and 125. The communication path 123 can connect the transmitter 115 to the receiver 148 and the communication path 125 can connect the transmitter 145 to the receiver 118. The communication channel 122-1 can be adapted to a variety of communication methodologies including, but not limited to, single-ended, differential, or others, and can also be adapted to carry a variety of modulation methodologies including, for example, PAM 2, PAM 4 and others. In an embodiment, the receivers and transmitters operate on differential signals. Differential signals are those that are represented by two complementary signals on different conductors, with the term “differential” representing the difference between the two complementary signals. The two complementary signals can be referred to as the “true” or “t” signal and the “complement” or “c” signal. All differential signals also have what is referred to as a “common mode,” which represents the average of the two differential signals. High-speed differential signaling offers many advantages, such as low noise and low power while providing a robust and high-speed data transmission.

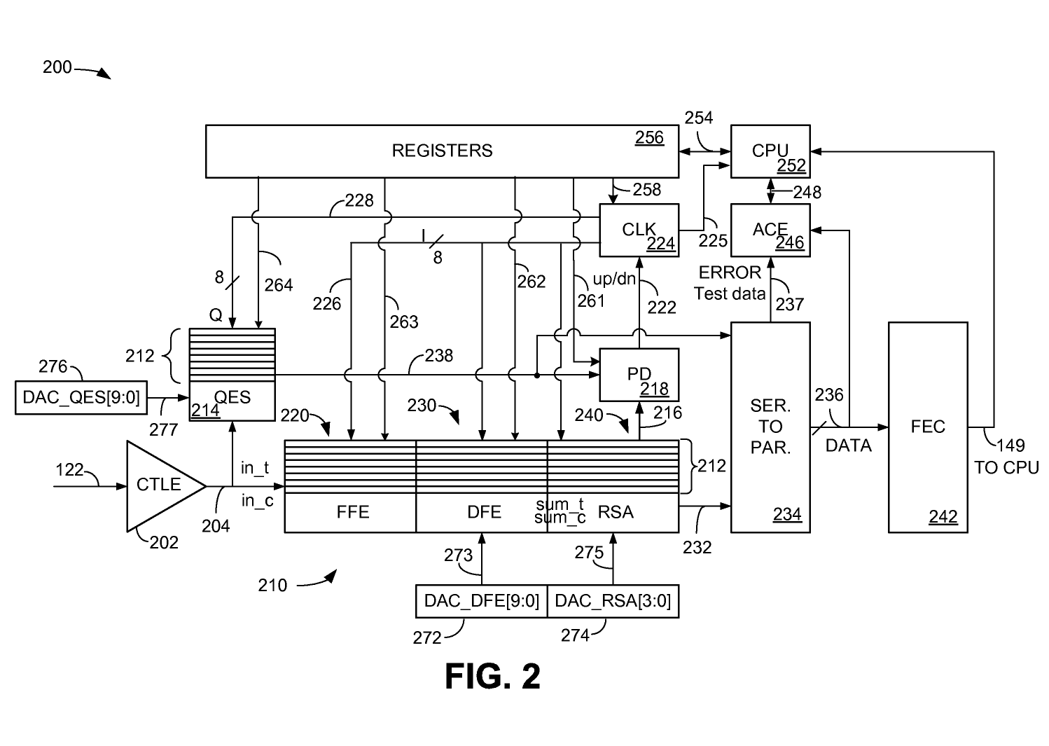

FIG. 2 is a schematic diagram illustrating an example receiver of FIG. 1. The receiver 200 can be any of the receivers illustrated in FIG. 1. The receiver 200 comprises a continuous time linear equalizer (CTLE) 202 that receives the information signal from the communication channel 122 (FIG. 1). The output of the CTLE 202 is provided to a quadrature edge selection (QES) element 214 and to a pipelined processing system 210. The pipelined processing system 210 comprises a pipelined feed forward equalizer (FFE) 220, a pipelined decision feedback equalizer (DFE) 230 and a regenerative sense amplifier (RSA) 240.

The reference to a “pipelined” processing methodology refers to the ability of the FFE 220, the DFE 230 and the RSA 240 to process 8 pipelined stages 212 (referred to below as sections D0 through D7) simultaneously.

The DFE 230 receives a threshold voltage input from a digital-to-analog converter (DAC) 272 over connection 273. The RSA 240 receives a threshold voltage input from a digital-to-analog converter (DAC) 274 over connection 275. The DAC 272 and the DAC 274 can be can be any type of DAC that can supply a threshold voltage input based on system requirements. In an embodiment, a single DAC 272 can be shared across the pipelined stages of the DFE 230, thus reducing cost and maximizing processing efficiency.

The RSA 240 converts an analog voltage into a complementary digital value. The output of the RSA 240 comprises data and in-phase pulse edge information and is provided over connection 216 to a phase detector (PD) 218. The output of the phase detector 218 comprises an update signal having, for example, an up/down command, and is provided over connection 222 to a clock (CLK) element 224. The clock element 224 is also referred to as an N-phase clock generation circuit, and provides an in-phase (I) clocking signal over connection 226 and provides a quadrature (Q) clocking signal over connection 228. The in-phase (I) clocking signal is provided to the pipelined FFE 220, the DFE 230, and to the RSA 240; and the quadrature (Q) clocking signal is provided to the QES element 214. The system and method for adaptive N-phase clock generation for an N-phase receiver can be implemented in various embodiments by the N-phase clock generation circuit 224.

The QES element 214 receives a threshold voltage input from a DAC 276 over connection 277. The DAC 276 can be any type of DAC that can supply a threshold voltage input based on system requirements.

The output of the RSA 240 on connection 232 is a digital representation of the raw, high speed signal prior to extracting any line coding, forward error correction, or demodulation to recover data. In the case of PAM 2, the output is a sequence of ones and zeros. In the case of PAM N, it is a sequence of N binary encoded symbols. For example, for PAM 4, the output comprises a string of four distinct symbols each identified by a different two bit digital word. The output of the RSA 240 is provided over connection 232 to a serial-to-parallel converter 234. The serial-to-parallel converter 234 converts the high speed digital data stream on connection 232 to a lower speed bus of parallel data on connection 236. The output of the serial-to-parallel converter 234 on connection 236 is the parallel data signal and is provided to a forward error correction (FEC) element 242. The output of the serial-to-parallel converter 234 on connection 237 is an error, or test, signal and is provided to an automatic correlation engine (ACE) 246. The error, or test, signal is used to drive system parameters to increase signal-to-noise ratio in the receiver 200, and can be generated in several ways. One way is to use samplers inside the QES element 214 to identify zero crossings (also called edge data, or the transition between data bits). Another method is to use auxiliary samplers inside the RSA element 240 to identify the high amplitude signals (equivalent to the open part of an eye diagram). So, for example, using the edge data method, if a sampler inside the QES element 214 began to detect a positive signal where the zero crossing point should occur, then the ERROR signal on connection 237 would increase, and various system parameters could be driven to reduce that error. The output of the FEC 242 is provided over connection 149 to the CPU 252.

The output of the ACE 246 is provided over connection 248 to the CPU 252. The implementation of the ACE 246 could be done with hardware on chip, firmware off chip, or a combination of hardware and firmware, and a CPU, in which case the CPU 252 would read and write to the ACE 246 over connection 248. The ACE 246 compares the received data to a pseudorandom binary sequence (PRBS) pattern and provides a correlation function to support implementation of a least minimum square (LMS) algorithm for tuning the receiver 200.

The CPU 252 is connected over a bi-directional link 254 to registers 256. The registers 256 store DFE filter coefficients, FFE controls, CTLE controls, RSA threshold voltage controls offset correction values for the RSA and QES elements, and controls for the DACs.

An output of the registers 256 on connection 261 is provided to the phase detector 218, an output of the registers 256 on connection 262 is provided to the pipelined DFE 230, an output of the registers 256 on connection 263 is provided to the pipelined FFE 220, and an output of the registers 256 on connection 264 is provided to the QES element 214. Although not shown for simplicity of illustration, the registers 256 also provide control outputs to the CTLE 202 and to all the DACs. In an embodiment, the output of the QES element 214 on connection 238 comprises data and quadrature pulse edge information and is provided to the phase detector 218 and the serial-to-parallel converter 234.

The elements in FIG. 2 generally operate based on a system clock signal that runs at a particular frequency, which corresponds to the baud rate of the data channel. A time period, referred to as a unit interval (UI) generally corresponds to a time period of one clock cycle of the system clock. For example, a transceiver could be communicating at 50 Gbps, using PAM4, the baud rate is 25 G baud per second, and one UI would be 40 ps= 1/25G. 1/25 G.

Generally, a receive signal on connection 204 is applied to an array of FFE/DFE/RSA/QES sections. If an array of N sections is implemented, then each section can process the receive signal at a rate of 1/(UI*N) which significantly relaxes power requirements compared to the standard (un-pipelined) processing.

For example, a 25 Gbaud receive signal could be processed by an array of 8 sections, each section running at 3.125 GHz. The start time for each section is offset by 1 UI from its neighboring section, so that when the outputs from all 8 sections are summed together (signal 232), it is updated at the original 25 Gbaud rate.

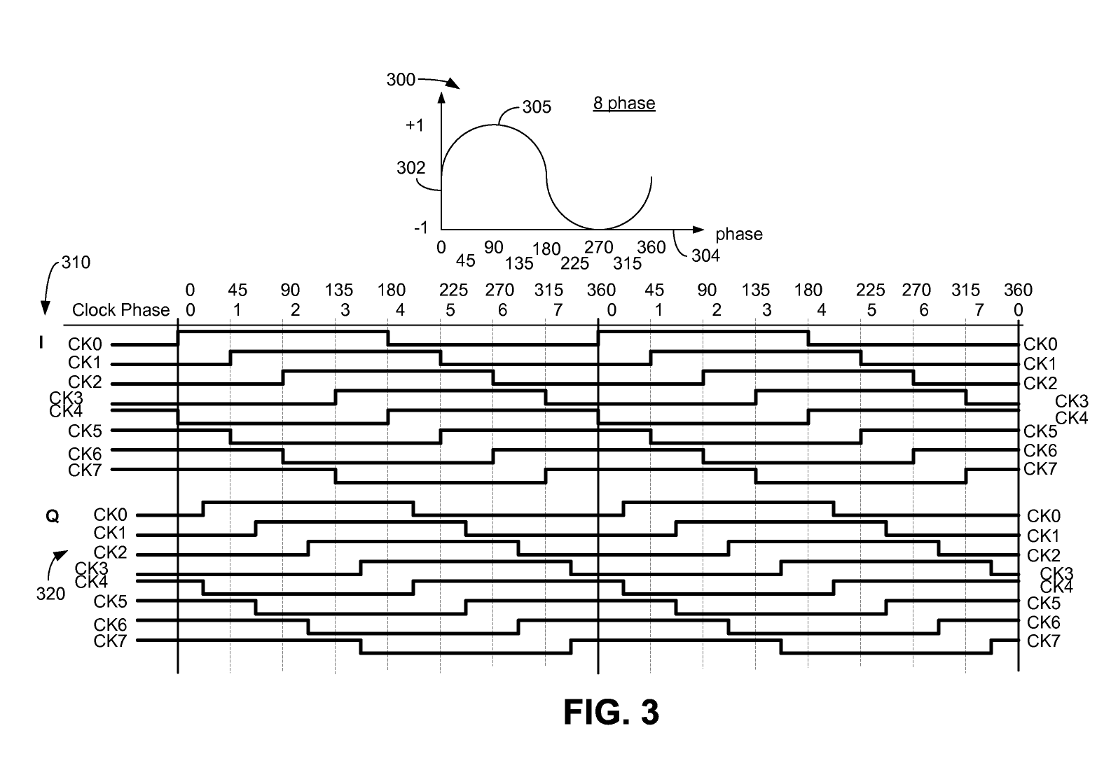

FIG. 3 is a schematic diagram illustrating example clock signals of the receiver of FIG. 2. A graphical example of the clock signal generated by the N-phase clock generation circuit 224 is shown in the graph 300. The vertical axis 302 of the graph 300 refers to relative amplitude in volts (V), with a normalized value range of between −1V and +1V. The horizontal axis 304 refers to the phase of the clock signal. In an embodiment, the clock signal is sampled at 45 degree intervals to generate the 8 clock phases in one clock cycle represented by the trace 305. The 8 clock phases are also shown as signal traces CK0 through CK7. The repeating periods “0” through “7” refer to system clock intervals, and the time between each repeating period is referred to as a ‘UI” or unit interval of the system clock. The in-phase clock signals 310 are illustrated as being offset from the quadrature clock signals 320 by ½ of a UI, which corresponds to ½ of a bit time after the in-phase clock, or 1/16 of the ⅛ frequency (22.5 degrees) clock shown by the trace 305.

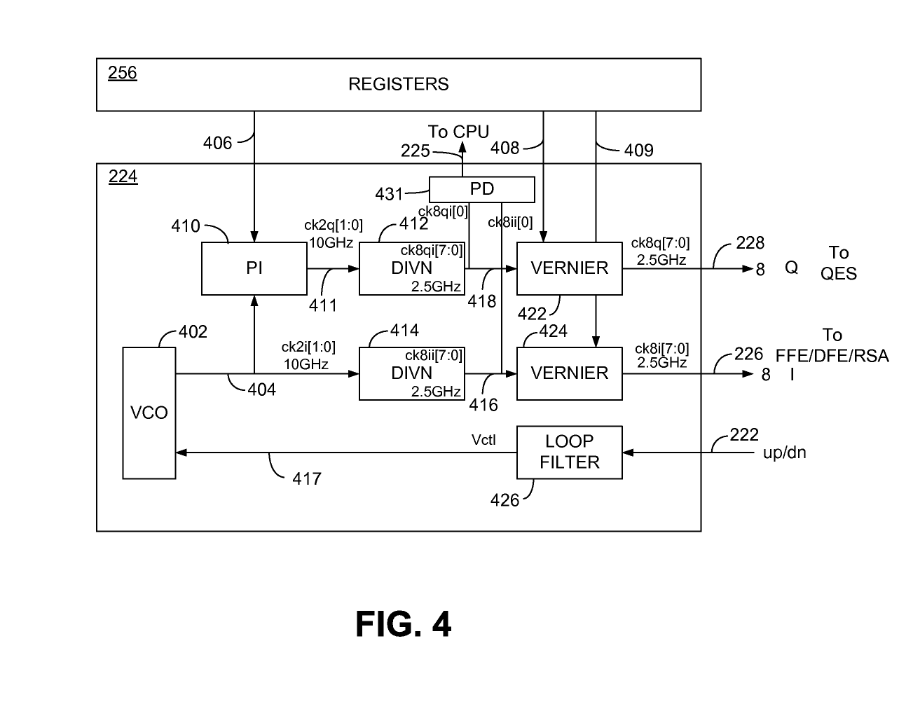

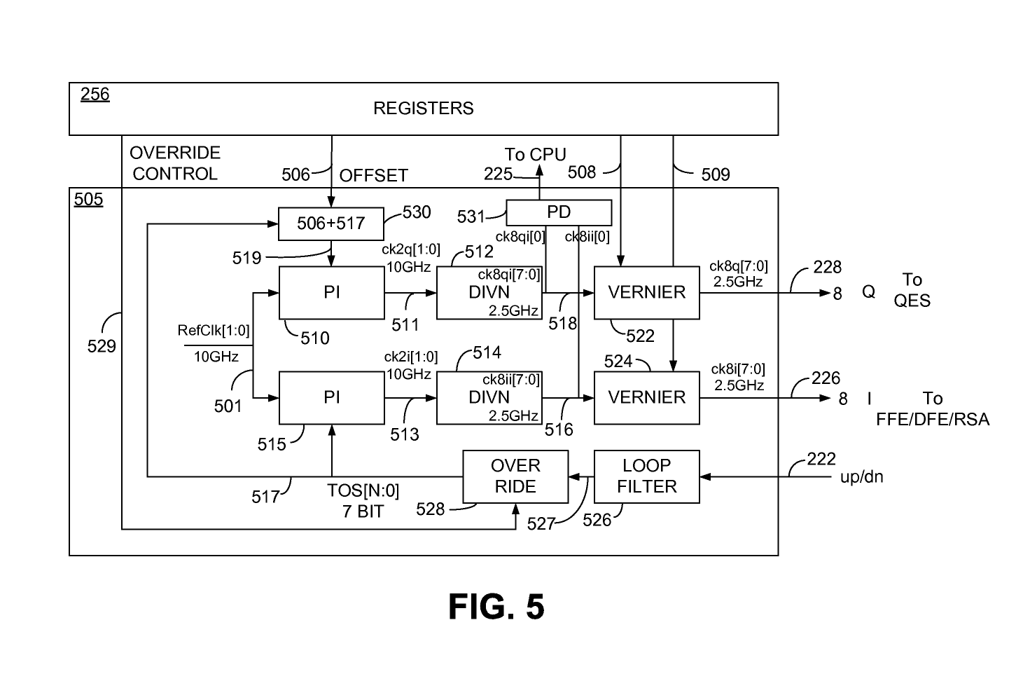

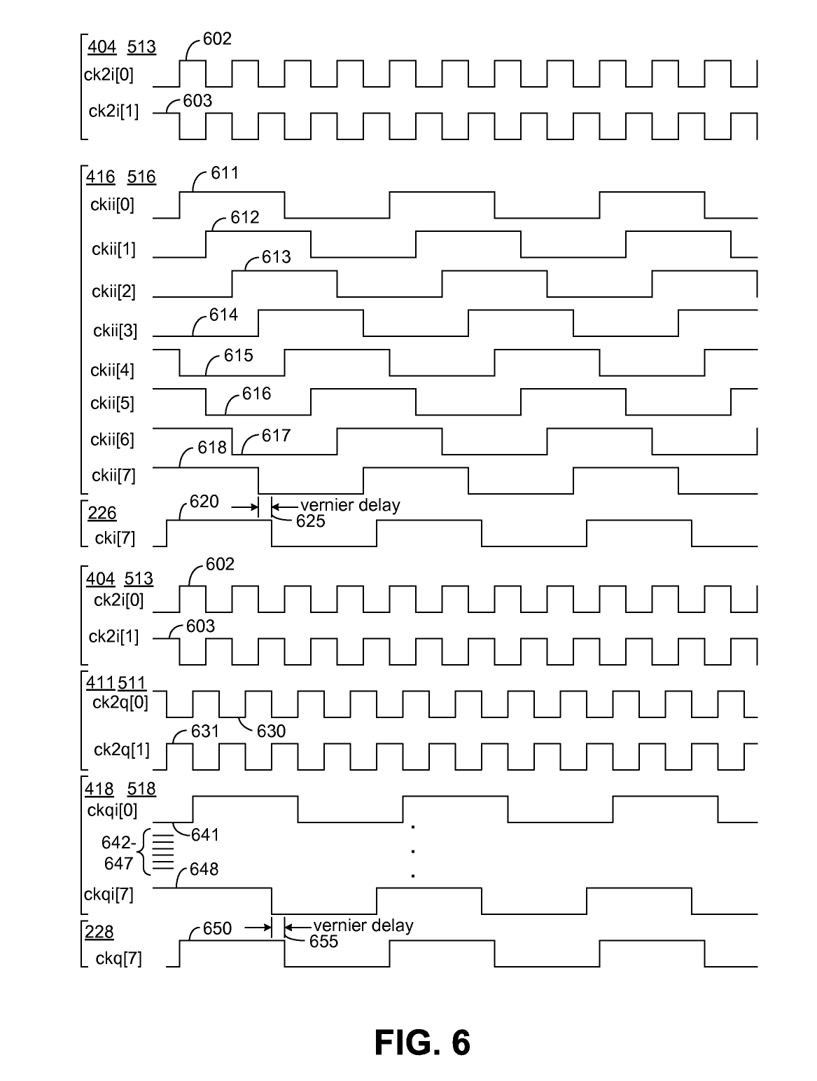

FIG. 4 is a block diagram illustrating an embodiment of the N-phase clock generation circuit 224 of FIG. 2. The signal traces relevant to FIG. 4 (and to FIG. 5 below), are shown in FIG. 6. The N-phase clock generation circuit 224 comprises a voltage controlled oscillator (VCO) 402, a phase interpolator 410, a quadrature divide by N (DivN) element 412, an in-phase divide by N (DivN) element 414, a quadrature vernier 422, an in-phase vernier 424 and a loop filter 426. The N-phase clock generation circuit 224 can operate on a variety of input clock frequencies, and, in this example, will be described as operating on a 10 GHz clock signal using a divide by 8 architecture to correspond to the 8 pipelined stages 212 (FIG. 2). However, other clock frequencies and other divisors are possible depending on the implementation.

In an embodiment, the VCO 402 provides a clock signal, ck2i[1:0], over connection 404 to the phase interpolator 410 and to the in-phase divide by N (divN) element 414. In an embodiment, the clock signal, ck2i[1:0] can be at a frequency of 10 GHz, but other frequencies are possible. In this example, the 10 GHz clock signal, ck2i[1:0], on connection 404 is an in-phase clock signal. The VCO receives a control signal, Vctl, over connection 417 from the loop filter 426. The loop filter 426 receives the up/down control signal from the phase detector 218 over connection 222 (FIG. 2). There are two possible approaches for the initial frequency that can be used for the output of the VCO (or the RefClk[1:0] input in FIG. 5). The input frequency can be equal to the channel baud rate or can be a frequency that is equal to half the baud rate. There are trade-offs between these two options. Using a baud rate clock provides a signal having two edges per symbol so the edges are aligned with both the edges of the symbol and the center of the symbol. For clock recovery this arrangement is very useful. However, generating and managing such a high frequency clock is difficult. Using a half baud rate clock reduces the high frequency challenges with the clock, but necessitates the creation of another edge if it is desirable to have clock edges on both the edge and the center of the received symbol. This extra edge is also used by the phase interpolator 410 to create quadrature clocks. In this embodiment, a half baud rate clock is assumed.

The phase interpolator 410 receives a control signal from the registers 256 over connection 406. The connections 406, 408 and 409 comprise the connection 258 of FIG. 2. The control for the phase interpolator 410 is a direct digital value or an encoded digital value defining the desired amount of phase shift in discrete steps based upon some resolution. This resolution is defined by the application and the desired phase shift. In an embodiment, the resolution can be 360 degrees divided by 128 for a step size of 2.8125 degrees. Such an application uses a 7 bit control value specifying phases from 0 degrees to 357.1875 degrees. The control signal should only be incremented or decremented by a small amount to avoid causing glitches on the output clock signal. In an embodiment, the control value is incremented or decremented by 1. For example, changing the control value on connection 406 from 127 to 0 will only cause a phase shift of 2.8127 degrees from 357.1875 to 360 degrees, which is the same as 0 degrees.

The phase interpolator 410 receives the input 10 GHz clock signal, ck2i[1:0], on connection 404 and generates an output 10 GHz clock signal, ck2q[1:0], on connection 411 that is shifted in phase from the input 10 GHz clock signal, ck2i[1:0], on connection 404, by an amount determined by the control signal on connection 406. The phase interpolator 410 can be cycled through phases continuously, effectively allowing for adjustment greater than a full period. In an embodiment, the phase interpolator generates a quadrature 10 GHz clock signal, ck2q[1:0], on connection 411 from the in-phase 10 GHz clock signal, ck2i[1:0], on connection 404. The input 10 GHz clock signal, ck2i[1:0], on connection 404 is illustrated in FIG. 6 as traces 602 and 603. The quadrature 10 GHz clock signal, ck2q[1:0], on connection 411 is illustrated in FIG. 6 as traces 630 and 631. The phase interpolator 410 will be described in greater detail below.

The in-phase 10 GHz clock signal, ck2i[1:0] on connection 404 is provided to the in-phase divide by N (DivN) element 414. In an embodiment, the in-phase divide by N (DivN) element 414 provides a divide by 8 function, but other divisors are possible. The quadrature 10 GHz clock signal, ck2q[1:0] on connection 411 is provided to the quadrature divide by N (DivN) element 412. In an embodiment, the quadrature divide by N (DivN) element 412 provides a divide by 8 function, but other divisors are possible.

The output of the in-phase divide by N (DivN) element 414 on connection 416 is a divided in-phase 2.5 GHz clock signal, ck8ii[7:0]; and the output of the quadrature divide by N (DivN) element 412 on connection 418 is a divided quadrature 2.5 GHz clock signal, ck8qi[7:0].

The output of the in-phase divide by N (DivN) element 414 on connection 416 is shown in FIG. 6 as traces 611 through 618, which correspond to the eight divided clock phases. The output of the quadrature divide by N (DivN) element 412 on connection 418 is shown in FIG. 6 as traces 641 through 648, with the traces corresponding to the signals ckqi[1] through ckqi[6] (642-647) not being shown for simplicity of illustration.

The divided in-phase 2.5 GHz clock signal, ck8ii[7:0] on connection 416 is provided to a vernier 424. The divided quadrature 2.5 GHz clock signal, ck8qi[7:0] on connection 418 is provided to a vernier 422. The vernier 422 receives a control signal from the registers 256 over connection 408 and the vernier 424 receives a control signal from the registers 256 over connection 409.

The verniers 422 and 424 are also referred to as “time verniers” and generally comprise programmable delay lines. An example implementation of the verniers 422 and 424 can comprise buffers driving a capacitance which generates a delay. The control signals on connections 408 and 409 can adjust the strength of the drivers (not shown), the amount of capacitance load, or a combination of both. The control for the verniers 422 and 424 can be a binary value or an encoded binary value. In an embodiment, the control signals on each of connections 408 and 409 can be a 4 bit binary value allowing 16 steps of time control that can be linear or non-linear with larger values creating larger steps. Each vernier 422 and 424 has an individual control, so that the verniers 422 and 424 can be independently set to different delays.

The output of the vernier 424 on connection 226 is a delayed in-phase 2.5 GHz clock signal, ck8i[7:0], and is provided to the FFE 220, DFE 230 and RSA 240 of FIG. 2 over connection 226. The clock signals on connection 226 correspond to the in-phase clock signals 310 shown in FIG. 3. A single example of one of the 8 delayed in-phase 2.5 GHz clock signals, ck8i[7:0], is shown in FIG. 6 as trace 620 (clock signal cki[7]) with the variable delay provided by the vernier 424 shown using reference numeral 625. Similar delayed clock signals cki[0] through cki[6] exist on connection 226, but are omitted from FIG. 6 for simplicity.

The output of the vernier 422 on connection 228 is a delayed quadrature 2.5 GHz clock signal, ck8q[7:0], and is provided to the QES element over connection 228. The clock signals on connection 228 correspond to the quadrature clock signals 320 shown in FIG. 3. A single example of one of the 8 delayed quadrature 2.5 GHz clock signals, ck8q[7:0], is shown in FIG. 6 as trace 650 (clock signal ckq[7]) with the variable delay provided by the vernier 422 shown using reference numeral 655. Similar delayed clock signals ckq[0] through ckq[6] exist on connection 228, but are omitted from FIG. 6 for simplicity.

In the embodiment of the N-phase clock generation circuit of FIG. 4, the output clock signals on connection 226 and 228 are aligned to the incoming data via a closed loop Phased Locked Loop (PLL). The VCO 402 and the loop filter 426 are integral to the PLL design and utilize the phase detector 218 (FIG. 2) to generate the up/down signals on connection 222 to control the frequency/phase of the VCO 402 to track the incoming data stream on connection 204 (FIG. 2). The design of such a PLL is known to those having ordinary skill in the art.

The phase interpolator 410 defines the phase between the quadrature clocks and the in-phase clocks. This phase alignment is performed, at least in part, with a phase detector 431 that is based upon one of the quadrature output clocks and one of the in-phase output clocks. In an embodiment, the phase detector 431 receives the LSB ck8qi[0] signal (trace 641 in FIG. 6) over connection 418 and the LSB ck8ii[0] signal (trace 611 of FIG. 6) over connection 416. The phase detector 431 provides an output to the CPU 252 (FIG. 2) over connection 225. The phase interpolator 410 can be stepped through its settings until the phase detector 431 changes state. This will be the point when the two clock signals, ck8qi[0] and ck8ii[0] are aligned. The phase interpolator 410 can then be stepped (via a control signal from the CPU 252 over connection 406) to create the proper phase relationship between the in-phase and quadrature clock signals. Typically, the phase interpolator 410 will be stepped through 45 degrees. The phase interpolator 410 can also be used to provide a quadrature clock that can sample the incoming signal at any point in the UI. This can allow for mapping the incoming eye at connection 204. This can also be used to adjust for eye offsets due to circuit imbalances or offsets.

The verniers 422 and 424 allow for independent adjustments to compensate for mismatches between the 8 stages for the in-phase and quadrature clock signals. These mismatches can be caused by systematic or random variations inherent in the design of multiple pipeline stages. In an embodiment, it is possible to use the verniers 422 and 424 for limited phase control if all 8 controls are adjusted the same amount as a backup to the phase interpolator 410.

FIG. 5 is a block diagram illustrating an alternative embodiment of the N-phase clock generation circuit 224 of FIG. 2. Elements in FIG. 5 that are similar to elements in FIG. 4 are numbered using the convention “5XX” where “5XX” in FIG. 5 refers to a corresponding element 4XX in FIG. 4. The N-phase clock generation circuit 505 comprises a quadrature phase interpolator 510, an in-phase phase interpolator 515, a quadrature divide by N (DivN) element 512, an in-phase divide by N (DivN) element 514, a quadrature vernier 522, an in-phase vernier 524, a loop filter 526, an override circuit 528 and a combiner circuit 530. The N-phase clock generation circuit 505 can operate on a variety of input clock frequencies, and, in this example, will be described as operating on a 10 GHz clock signal using a divide by 8 architecture. However, other clock frequencies and other divisors are possible depending on the implementation.

In an embodiment, an input reference clock signal, RefClk[1:0], is provided over connection 501 to the quadrature phase interpolator 510 and to the in-phase phase interpolator 515. In an embodiment, the input reference clock signal, RefClk[1:0] is a half baud rate clock and can be at a frequency of 10 GHz, but other frequencies are possible. For the implementation in FIG. 5, the input reference clock signal, RefClk[1:0], is phase locked to the same clock used for the transmitter (not shown) sending the data. The in-phase phase interpolator 515 receives a control signal, TOS[N:0], over connection 517 from the loop filter 526, through the override circuit 528. The loop filter 526 receives the up/down control signal from the phase detector 218 over connection 222 (FIG. 2). The up/down control signals on connection 222 is the output of the phase detector 218 (FIG. 2). The phase detector 218 evaluates information about the recovered main data and edge data and determines if the sample point is either early or late relative to the center of the eye. If the sample point is early, then the phase detector 218 creates an up control signal. If the sample point is late, then the phase detector 218 creates a down control signal.

The quadrature phase interpolator 510 receives a control signal from the combiner circuit 530 over connection 519. The combiner circuit receives the control signal over connection 517 and also receives a control signal from the registers 256 over connection 506. The control signal for the phase interpolator 515 over connection 517 is the same 7 bit control (in this embodiment) as the control signal for the phase interpolator 510, except that the phase interpolator 510 is also provided a 7 bit offset value over connection 506. The loop filter 526 comprises a digital circuit that processes the up/down signals on connection 222 and creates the 7 bit digital output on connection 527 that increments or decrements by single counts. In normal operation, the phase interpolator 510 and the phase interpolator 515 track each other, but with an offset. This offset is provided from the registers 256 over connection 506 to the combiner circuit 530. The combiner circuit 530 combines the offset on connection 506 with the control signal on connection 517, discarding any remainder, and provides a 7 bit control signal to the phase interpolator 510 over connection 519. The signal on connection 519 comprises the 7 bit control signal on connection 517, plus the 7 bit offset value on connection 506. In addition, for test and debugging, an override element 528, upon receipt of an override control signal over connection 529 from the registers 256, can override the control signal on connection 517. The signal on connection 529 can comprise an override control bit, which selects the override function, and an override value, which is used when the override is in effect. When the override is in effect the offset between the phase interpolator 510 and the phase interpolator 515 will still be determined by the offset value on connection 506. The connections 506, 508, 509 and 529 comprise the connection 258 of FIG. 2.

The quadrature phase interpolator 510 receives the 10 GHz input reference clock signal, RefClk[1:0], on connection 501 and generates a quadrature 10 GHz clock signal, ck2q[1:0], on connection 511. The quadrature 10 GHz clock signal, ck2q[1:0], on connection 511 is illustrated in FIG. 6 as traces 630 and 631.

The in-phase phase interpolator 515 receives the 10 GHz input reference clock signal, RefClk[1:0], on connection 501 and generates an in-phase 10 GHz clock signal, ck2i[1:0], on connection 513. The in-phase 10 GHz clock signal, ck2i[1:0], on connection 513 is illustrated in FIG. 6 as traces 602 and 603.

The output 10 GHz clock signal, ck2q[1:0], on connection 511 is shifted in phase from the output 10 GHz clock signal, ck2i[1:0], on connection 513 by an amount determined by the control signals provided to the quadrature phase interpolator 510 and the in-phase phase interpolator 515, as described above. The control signals provided to the in-phase phase interpolator 515 and the quadrature phase interpolator 510 determines the phase difference between the quadrature 10 GHz clock signal, ck2q[1:0], on connection 511 and the in-phase 10 GHz clock signal, ck2i[1:0], on connection 513. As stated above, the quadrature phase interpolator 510 and the in-phase phase interpolator 515 can be cycled through phases continuously, effectively allowing for adjustment greater than a full clock period.

The in-phase 10 GHz clock signal, ck2i[1:0], on connection 513 is provided to the in-phase divide by N (DivN) element 514. In an embodiment, the in-phase divide by N (DivN) element 514 provides a divide by 8 function, but other divisors are possible. The quadrature 10 GHz clock signal, ck2q[1:0], on connection 511 is provided to the quadrature divide by N (DivN) element 512. In an embodiment, the quadrature divide by N (DivN) element 512 provides a divide by 8 function, but other divisors are possible.

The output of the in-phase divide by N (DivN) element 514 on connection 516 is a divided in-phase 2.5 GHz clock signal, ck8ii[7:0]; and the output of the quadrature divide by N (DivN) element 512 on connection 518 is a divided quadrature 2.5 GHz clock signal, ck8qi[7:0].

The output of the in-phase divide by N (DivN) element 514 on connection 516 is shown in FIG. 6 as traces 611 through 618, which correspond to the divided eight clock phases. The output of the quadrature divide by N (DivN) element 512 on connection 518 is shown in FIG. 6 as traces 641 through 648, with the traces corresponding to the signals ckqi[1] through ckqi[6] (642-647) not being shown for simplicity of illustration.

The divided in-phase 2.5 GHz clock signal, ck8ii[7:0], on connection 516 is provided to a vernier 524. The divided quadrature 2.5 GHz clock signal, ck8qi[7:0], on connection 518 is provided to a vernier 522. The vernier 522 receives a control signal from the registers 256 over connection 508 and the vernier 524 receives a control signal from the registers 256 over connection 509.

The verniers 522 and 524 are referred to as “time verniers” and generally comprise programmable delay lines. An example implementation of the verniers 522 and 524 can comprise buffers driving a capacitance which generates a delay. The control signals on connections 508 and 509 can adjust the strength of the drivers (not shown), the amount of capacitance load, or a combination of both. As mentioned above, the control for the verniers 522 and 524 can be a binary value or an encoded binary value. In an embodiment, the control signals on each of connections 508 and 509 can be a 4 bit binary value allowing 16 steps of time control that can be linear or non-linear with larger values creating larger steps. Each vernier 522 and 524 has an individual control, so that the verniers 522 and 524 can be independently set to different delays.

The output of the vernier 524 on connection 226 is a delayed in-phase 2.5 GHz clock signal, ck8i[7:0], and is provided to the FFE 220, DFE 230 and RSA 240 of FIG. 2 over connection 226. The clock signals on connection 226 correspond to the in-phase clock signals 310 shown in FIG. 3. A single example of one of the 8 delayed in-phase 2.5 GHz clock signals, ck8i[7:0], is shown in FIG. 6 as trace 620 (clock signal cki[7]) with the variable delay provided by the vernier 524 shown using reference numeral 625. Similar delayed clock signals cki[0] through cki[6] exist on connection 226, but are omitted from FIG. 6 for simplicity.

The output of the vernier 522 on connection 228 is a delayed quadrature 2.5 GHz clock signal, ck8q[7:0], and is provided to the QES element over connection 228. The clock signals on connection 228 correspond to the quadrature clock signals 320 shown in FIG. 3. A single example of one of the 8 delayed in-phase 2.5 GHz clock signals, ck8q[7:0], is shown in FIG. 6 as trace 650 (clock signal ckq[7]) with the delay provided by the vernier 522 shown using reference numeral 655. Similar delayed clock signals ckq[0] through ckq[6] exist on connection 228, but are omitted from FIG. 6 for simplicity.

In the embodiment of the N-phase clock generation circuit of FIG. 5, the output clock signals on connection 226 and 228 are aligned to the incoming data via a closed loop Delay Locked Loop (DLL). The loop filter 526 is integral to the DLL design and utilizes the phase detector 218 (FIG. 2) to generate the up/down signals on connection 222 to control the phase of the phase interpolators 510 and 515 to track the incoming data stream. The design of such a DLL is known to those having ordinary skill in the art.

The phase interpolators 510 and 515 define the phase difference between the quadrature output clocks and the in-phase clocks. This phase alignment is performed with a phase detector 531 that is based upon one of the quadrature output clocks and one of the in-phase output clocks. In an embodiment, the phase detector 531 receives the LSB ck8qi[0] signal (trace 641 in FIG. 6) over connection 518 and the LSB ck8ii[0] signal (trace 611 of FIG. 6) over connection 516. The phase detector 531 provides an output to the CPU 252 (FIG. 2) over connection 225. The phase interpolators 510 and 515 can be stepped through their settings until the phase detector 531 changes state. This will be the point when the two clock signals, ck8qi[0] and ck8ii[0] are aligned. The phase interpolators 510 and 515 can then be stepped (via a control signal from the CPU 252 over connection 506) to create the proper phase relationship between the in-phase and quadrature clock signals. Typically, this will have the phase interpolators 510 and 515 stepped through 45 degrees.

The purpose of using two phase interpolators is to allow for different phases between the in-phase clock signals and the quadrature clock signals. As described above in FIG. 4, the phase interpolator 510 can be used to align the in-phase and quadrature clock signals, and then the quadrature clock signals can be offset from the in-phase clock signals to allow for proper eye centering or for eye mapping of the signal on connection 204.

As stated above, the verniers 522 and 524 allow for adjustments to compensate for mismatches between the 8 stages of the in-phase and quadrature clock signals. These mismatches can be caused by systematic or random variations inherent in the design of multiple pipeline stages. In an embodiment, it is possible to use the verniers 522 and 524 for limited phase control if all 8 controls are adjusted the same amount as a backup to the phase interpolators 510 and 515.

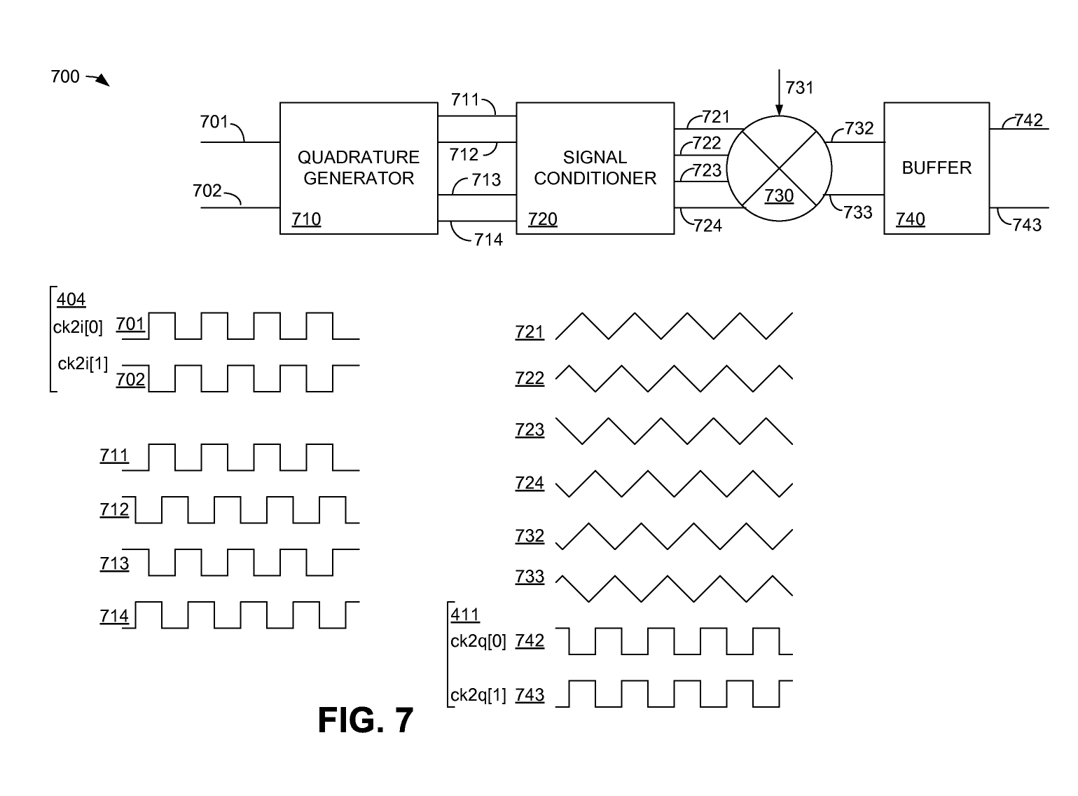

FIG. 7 is a block diagram showing an embodiment of a phase interpolator that can be implemented in FIG. 4 and FIG. 5. The example phase interpolator 700 comprises a quadrature generator 710, a signal conditioner 720, a mixer 730 and a buffer 740. The quadrature generator receives incoming complementary clock signals on connections 701 and 702, and creates new complementary clock signals that are 90 degrees out of phase on connections 711, 712, 713 and 714. Examples of the signals on connections 701, 702, 711, 712, 713 and 714 are also shown in FIG. 7 for reference. The signals on connections 701 and 702 correspond to the signals on connection 404 in FIG. 4. The input to the phase interpolators 510 and 515 in FIG. 5 are the complementary RefClk[1:0] signals on connection 501.

The signals on connections 711, 712, 713 and 714 are provided to the signal conditioner 720. The signal conditioner 720 converts the quadrature clock signals into triangular waves on connections 721, 722, 723 and 724. Examples of the signals on connections 721, 722, 723 and 724 are also shown for reference. The signals on connections 721, 722, 723 and 724 are provided to the mixer 730. The triangular shaped signals 721, 722, 723 and 724 allow the mixer 730 to operate with good linearity.

The mixer 730 uses the control signal on connection 731 (connection 406 in FIG. 4 and connection 506 in FIG. 5) to select which incoming signals to mix and the ratio in which they are mixed. By mixing the voltages of the incoming triangle shaped waves on connections 721, 722, 723 and 724, a phase shift is created in which there is a relationship between the voltage and time (phase) of the incoming signals. For example if it is desired that the output on connection 732 have a phase centered between the phase of the input signals on connections 721 and 722, the mixer would be controlled such that the voltage on connection 732 is equal to the sum of ½ the voltage on connection 721 and ½ the voltage on connection 722. The output on connection 732 can be a function of the mixture of any two adjacent input signals, so it can be a function of the signals on connection 721 and connection 722, a function of the signals on connection 722 and connection 723, a function of the signals on connection 723 and connection 724, or a function of the signals on connection 724 and connection 721. The output of the mixer 730 on connection 733 is the complement of the signal on connection 732 and is a function of the complement of the signals that are used on connection 732, so if the signal on connection 732 is a function of the signal on connections 721 and 722, then the signal on connection 733 is a similar function of the signals on connections 723 and 724.

The buffer 740 squares the input triangle waves to generate a square wave output on connections 742 and 743. The connections 742 and 743 correspond to the connection 411 in FIGS. 4 and 511 in FIG. 5.

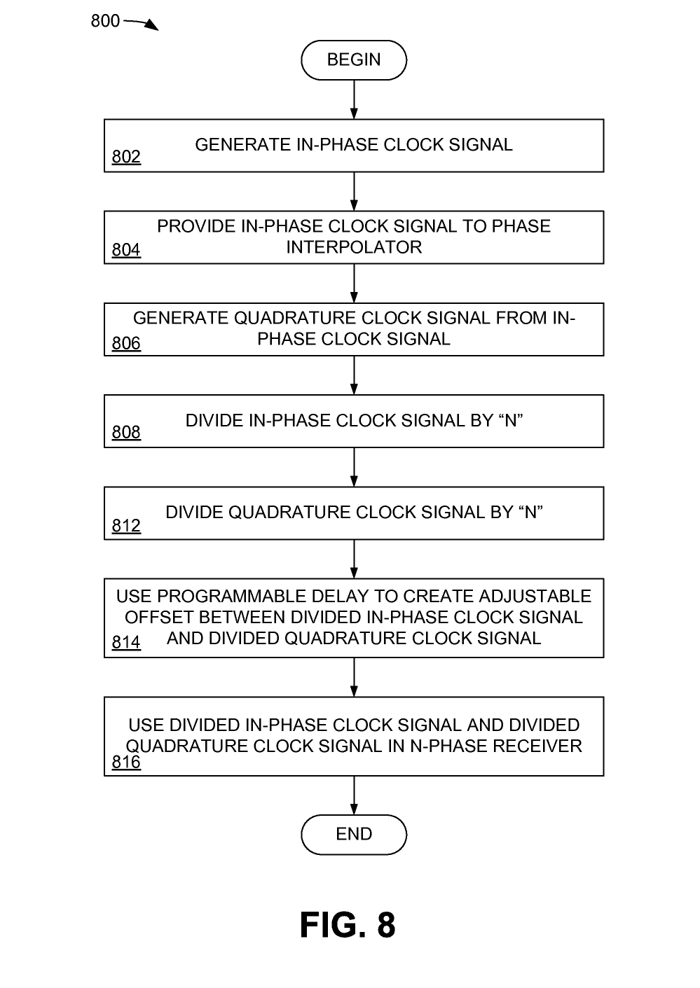

FIG. 8 is a flow chart describing an embodiment of a method for adaptive N-phase clock generation for an N-phase receiver. The blocks in the flow chart 800 can be performed in or out of the order shown.

In block 802, an in-phase clock signal is generated. In an embodiment, the in-phase clock signal can be the clock signal, ck2i[1:0] generated by the VCO 402 (FIG. 4).

In block 804 the in-phase clock signal is provided to the phase interpolator 410 (FIG. 4).

In block 806, a quadrature clock signal is generated from the in-phase clock signal. In an embodiment, the phase interpolator 410 receives the in-phase 10 GHz clock signal, ck2i[1:0], on connection 404 and generates a quadrature 10 GHz clock signal, ck2q[1:0], on connection 411 that is shifted in phase from the in-phase 10 GHz clock signal, ck2i[1:0], on connection 404 by an amount determined by the control signal on connection 406.

In block 808, the in-phase clock signal is divided by “N.” In an embodiment, the in-phase 10 GHz clock signal, ck2i[1:0], on connection 404 is divided by “N” by the in-phase divide by N (DivN) element 414. In an embodiment, the in-phase divide by N (DivN) element 414 provides a divide by 8 function, but other divisors are possible.

In block 812, the quadrature clock signal is divided by “N.” In an embodiment, the quadrature 10 GHz clock signal, ck2q[1:0], on connection 411 is divided by “N” by the quadrature divide by N (DivN) element 412. In an embodiment, the quadrature divide by N (DivN) element 412 provides a divide by 8 function, but other divisors are possible.

In block 814, a programmable delay is used to create an adjustable offset between the divided in-phase clock signal and the divided quadrature clock signal. In an embodiment, the divided in-phase 2.5 GHz clock signal, ck8ii[7:0], on connection 416 is provided to a vernier 424; and the divided quadrature 2.5 GHz clock signal, ck8qi[7:0] on connection 418 is provided to a vernier 422. The vernier 422 receives a control signal from the registers 256 over connection 408 and the vernier 424 receives a control signal from the registers 256 over connection 409.

In block 816, the in-phase 2.5 GHz clock signal, ck8i[7:0], is provided to the FFE 220, DFE 230 and RSA 240 of FIG. 2 over connection 226; and the quadrature 2.5 GHz clock signal, ck8q[7:0], is provided to the QES element over connection 228.

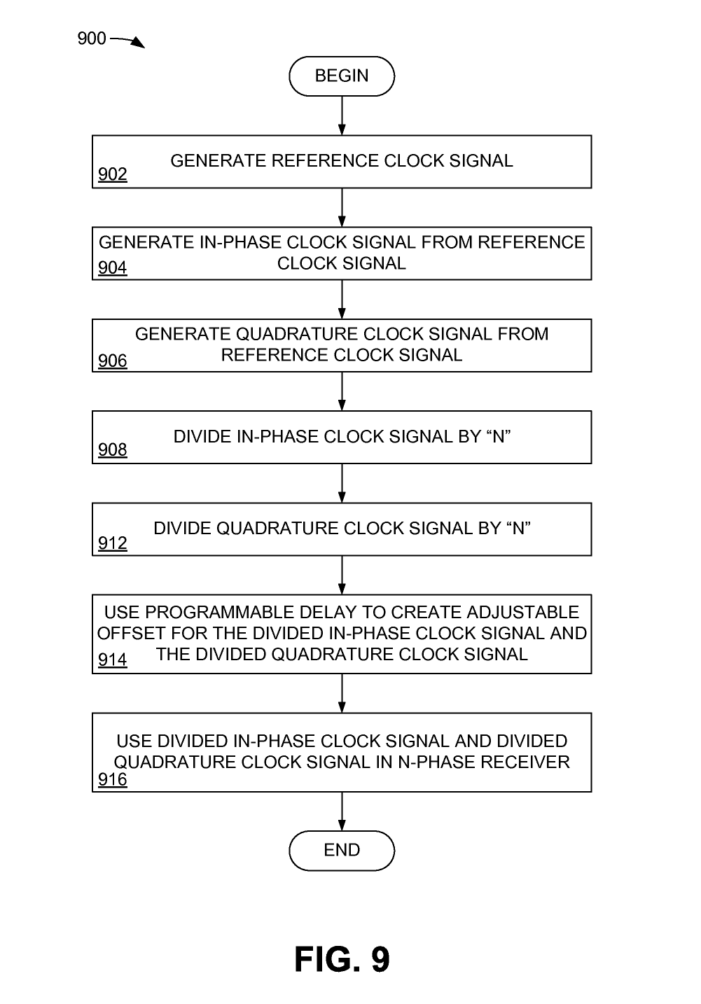

FIG. 9 is a flow chart describing an embodiment of a method for adaptive N-phase clock generation for an N-phase receiver. The blocks in the flow chart 900 can be performed in or out of the order shown.

In block 902, a reference clock signal is generated.

In block 904, an in-phase clock signal is generated from the reference clock. In an embodiment, the in-phase phase interpolator 515 receives the 10 GHz input reference clock signal, RefClk[1:0], on connection 501 and generates an in-phase 10 GHz clock signal, ck2i[1:0], on connection 513.

In block 906, a quadrature clock signal is generated from the reference clock signal. In an embodiment, The quadrature phase interpolator 510 receives the 10 GHz input reference clock signal, RefClk[1:0], on connection 501 and generates a quadrature 10 GHz clock signal, ck2q[1:0], on connection 511.

The output 10 GHz clock signal, ck2q[1:0], on connection 511 is shifted in phase from the output 10 GHz clock signal, ck2i[1:0], on connection 513 by an amount determined by the quadrature phase interpolator 510 and the in-phase phase interpolator 515. The in-phase phase interpolator 515 is controlled by the control signal on connection 517 and the quadrature phase interpolator 510 is controlled by the control signal on connection 517 and a control (offset) signal on 506 to generate a combined control signal on connection 519 to determine the phase difference between the quadrature 10 GHz clock signal, ck2q[1:0], on connection 511 and the in-phase 10 GHz clock signal, ck2i[1:0], on connection 513.

In block 908, the in-phase clock signal is divided by “N.” In an embodiment, the in-phase 10 GHz clock signal, ck2i[1:0], on connection 513 is divided by “N” by the in-phase divide by N (DivN) element 514. In an embodiment, the in-phase divide by N (DivN) element 514 provides a divide by 8 function, but other divisors are possible.

In block 912, the quadrature clock signal is divided by “N.” In an embodiment, the quadrature 10 GHz clock signal, ck2q[1:0], on connection 511 is divided by “N” by the quadrature divide by N (DivN) element 512. In an embodiment, the quadrature divide by N (DivN) element 512 provides a divide by 8 function, but other divisors are possible.

In block 914, a programmable delay is used to create an adjustable offset for the divided in-phase clock signal and for the divided quadrature clock signal. In an embodiment, the divided in-phase 2.5 GHz clock signal, ck8ii[7:0], on connection 516 is provided to a vernier 524; and the divided quadrature 2.5 GHz clock signal, ck8qi[7:0], on connection 518 is provided to a vernier 522. The vernier 522 receives a control signal from the registers 256 over connection 508 and the vernier 524 receives a control signal from the registers 256 over connection 509.

In block 916, the in-phase 2.5 GHz clock signal, ck8i[7:0], is provided to the FFE 220, DFE 230 and RSA 240 of FIG. 2 over connection 226; and the quadrature 2.5 GHz clock signal, ck8q[7:0], is provided to the QES element over connection 228.

This disclosure describes the invention in detail using illustrative embodiments. However, it is to be understood that the invention defined by the appended claims is not limited to the precise embodiments described.

What is claimed is:

1. An N-phase clock generation circuit, comprising:
an input clock signal comprising a first phase signal;
a phase interpolator configured to receive the input clock signal and generate a second phase signal;
a first divider element configured to receive the first phase signal and generate an in-phase divided clock signal;
a second divider element configured to receive the second phase signal and generate a quadrature divided clock signal;
a first delay element configured to receive the in-phase divided clock signal and an in-phase control signal, the first delay element configured to generate a delayed in-phase divided clock signal; and
a second delay element configured to receive the quadrature divided clock signal and a quadrature control signal, the second delay element configured to generate a delayed quadrature divided clock signal.

2. The circuit of claim 1, further comprising:
a loop filter configured to generate a control voltage; and
a voltage controlled oscillator configured to receive the control voltage and configured to generate the input clock signal.

3. The circuit of claim 2, further comprising:
a phase detector configured to receive a least significant bit (LSB) of the in-phase divided clock signal and a least significant bit (LSB) of the quadrature divided clock signal, the phase interpolator configured to be adjusted until the phase detector changes state, the state change indicating that the LSB of the in-phase divided clock signal and the LSB of the quadrature divided clock signal are aligned.

4. The circuit of claim 3, wherein the first delay element and the second delay element comprise individually adjustable programmable delay elements and allow for adjustments to compensate for mismatches between N stages of the in-phase divided clock signal and N stages of the quadrature divided clock signal.

5. The circuit of claim 1, further comprising:
a loop filter configured to generate a control voltage for controlling a plurality of phase interpolators for generating the first phase signal and the second phase signal.

6. The circuit of claim 5, further comprising:
a phase detector configured to receive a least significant bit (LSB) of the in-phase divided clock signal and a least significant bit (LSB) of the quadrature divided clock signal, the plurality of phase interpolators configured to be adjusted until the phase detector changes state, the state change indicating that the LSB of the in-phase divided clock signal and the LSB of the quadrature divided clock signal are aligned.

7. The circuit of claim 6, wherein the first delay element and the second delay element comprise individually adjustable programmable delay elements and allow for adjustments to compensate for mismatches between N stages of the in-phase divided clock signal and N stages of the quadrature divided clock signal.

8. The circuit of claim 1, wherein the delayed in-phase divided clock signal comprises 8 clock phases and the delayed quadrature divided clock signal comprises 8 clock phases.

9. The circuit of claim 8, wherein each of the 8 clock phases of the delayed in-phase divided clock signal and each of the 8 clock phases of the delayed quadrature divided clock signal is delayed by the same amount.

10. A method for generating an N-phase clock signal, comprising:
providing an input clock signal comprising a first phase signal;
receiving the input clock signal and generating a second phase signal;
receiving the first phase signal and generating an in-phase divided clock signal;
receiving the second phase signal and generating a quadrature divided clock signal;
receiving the in-phase divided clock signal and generating a delayed in-phase divided clock signal; and
receiving the quadrature divided clock signal and generating a delayed quadrature divided clock signal.

11. The method of claim 10, further comprising:
generating a control voltage; and
using the control voltage to generate the input clock signal.

12. The method of claim 11, further comprising:
receiving a least significant bit (LSB) of the in-phase divided clock signal and a least significant bit (LSB) of the quadrature divided clock signal; and
using the least significant bit (LSB) of the in-phase divided clock signal and a least significant bit (LSB) of the quadrature divided clock signal to generate the quadrature divided clock signal.

13. The method of claim 12, further comprising individually adjusting the delayed in-phase divided clock signal and the delayed quadrature divided clock signal to compensate for mismatches between N stages of the in-phase divided clock signal and N stages of the quadrature divided clock signal.

14. The method of claim 10, further comprising:
generating a control voltage; and
using the control voltage to generate the first phase signal and the second phase signal.

15. The method of claim 14, further comprising:
receiving a least significant bit (LSB) of the in-phase divided clock signal and a least significant bit (LSB) of the quadrature divided clock signal; and
using the significant bit (LSB) of the in-phase divided clock signal and a least significant bit (LSB) of the quadrature divided clock signal to generate the quadrature divided clock signal.

16. The method of claim 15, further comprising individually adjusting the delayed in-phase divided clock signal and the delayed quadrature divided clock signal to compensate for mismatches between N stages of the in-phase divided clock signal and N stages of the quadrature divided clock signal.

17. The method of claim 10, wherein the delayed in-phase divided clock signal comprises 8 clock phases and the delayed quadrature divided clock signal comprises 8 clock phases.

18. The method of claim 17, wherein each of the 8 clock phases of the delayed in-phase divided clock signal and each of the 8 clock phases of the delayed quadrature divided clock signal is delayed by the same amount.

19. An N-phase clock generation circuit, comprising:
an input clock signal comprising a first phase signal;
a phase interpolator configured to receive the input clock signal and generate a second phase signal;
a first divider element configured to receive the first phase signal and generate an in-phase divided clock signal;
a second divider element configured to receive the second phase signal and generate a quadrature divided clock signal;
a first delay element configured to receive the in-phase divided clock signal and an in-phase control signal, the first delay element configured to generate a delayed in-phase divided clock signal;
a second delay element configured to receive the quadrature divided clock signal and a quadrature control signal, the second delay element configured to generate a delayed quadrature divided clock signal;
a loop filter configured to generate a control voltage;
a voltage controlled oscillator configured to receive the control voltage and configured to generate the input clock signal; and
a phase detector configured to receive a least significant bit (LSB) of the in-phase divided clock signal and a least significant bit (LSB) of the quadrature divided clock signal, the phase interpolator configured to be adjusted until the phase detector changes state, the state change indicating that the LSB of the in-phase divided clock signal and the LSB of the quadrature divided clock signal are aligned.

20. The circuit of claim 19, wherein the first delay element and the second delay element comprise individually adjustable programmable delay elements and allow for adjustments to compensate for mismatches between N stages of the in-phase divided clock signal and N stages of the quadrature divided clock signal.
